(19) United States
(12) Patent Application Publication
(10) Pub. No.: US 2016/0320437 A1
(43) Pub. Date: Nov. 3, 2016

(54) Frequency Measuring Method and Measuring Device For Electricity System

(71) Applicants: XJ GROUP CORPORATION, Xuchang (CN); XJ ELECTRIC CO.,LTD, Xuchan (CN); XUCHANG XJ SOFTWARE TECHNOLOGIES LTD, Xuchang (CN); STATE GRID CORPORATION OF CHINA, Beijing (CN)

(72) Inventors: Li Wang, Xuchang (CN); Chuankun Ni, Xuchang (CN); Baowei Li, Xuchang (CN); Xu Li, Xuchang (CN); Wenzheng Li, Xuchang (CN); Yanmei Tang, Xuchang (CN); Xin Shi, Xuchang (CN); Huizhen Hao, Xuchang (CN); Liping Meng, Xuchang (CN)

(73) Assignees: XJ GROUP CORPORATION; XJ ELECTRIC CO.,LTD

(21) Appl. No.: 15/075,793

(22) Filed: Mar. 21, 2016

(30) Foreign Application Priority Data
Apr. 30, 2015 (CN) 201510216704.7

(51) Int. Cl. G01R 23/02

(52) U.S. Cl. CPC G01R 23/02

(57) ABSTRACT

The invention relates to a frequency measuring method and measuring device. The method comprises: firstly sampling the current signal to be measured, and discretizing the sampled signals; secondly obtaining sampling matrixes [Iₙ] and [Iₙ,] of the current signal to be measured at time n and time n−1 from the discrete sampled signals, setting a reference frequency f_{ref}, constructing a reference voltage signal u(t) from f_{ref}, and discretizing u(t) to gain reference matrix; finally, attaining phase values of time n and time n−1 from the eigenvalues of matrixes [Iₙ]⁺[U] and [Iₙ₋₁]⁺[U], and determining a calculation frequency f_{comp}. The invention uses sampled matrixes constructed from the reference signals and the signals to be measured. Through QR decomposition and similarity transformation of matrixes and the eigenvalues calculation of the corresponding matrixes, phases of the matrixes to be measured are gained, and the frequencies of the signals to be measured are calculated through the phase difference between the former and the latter sampling moment. The solution simplifies calculating process and reduces calculation, in comparison to the prior art, and can calculate the frequencies of the sinusoidal signals quickly and precisely in the power frequency data window.

### TECHNICAL FIELD

The invention relates to a frequency measuring method for an electricity system, which belongs to the technical field of electricity systems.

### BACKGROUND

The frequency is one of important electrical parameters in electricity systems, and it is very important both in theory and practice to research the frequency measuring algorithms for an electricity system. The frequency is an important indicator for evaluating the quality of electricity energy during electricity systems operate normally, and is an important basis for determining system failures when electricity systems are in failure.

The current frequency measuring algorithms for electricity systems are mainly based on Discrete Fourier Transform (DFT) method. If a sampling rate and data window are properly selected, this method can correctly obtain model parameters for observation models (assuming that D=0). However, in view that real measurements are usually deviated from ideal conditions, the DFT algorithm has an inherent characteristic, that is, is insensitive to the harmonic component. Its precision is largely reduced when signals are changed slowly in the dynamic condition. In addition, the frequency measuring errors also occurs due to a potential restraint of data window length, when the actual frequency is deviated from the nominal frequency. An improved algorithm can reduce measuring errors to some degree in case that harmonics and noises are taken into account, but it has drawbacks of calculation growing and time tag, and the like. In electricity systems, transient signals after failure contain a large number of integral harmonics, non-integral harmonics and decaying DC components, in addition to a power frequency component. The present algorithms are largely affected by these components when calculating the frequency.

For example, a Chinese patent CN 101852826A discloses a harmonic analysis method for an electricity system which proceeds with approximating for three times, regulating the Fourier Transform complex coefficient in each approximation and regulating the sample amounts in each sampling cycle, and finally attains a fundamental frequency value (i.e. the value to be calculated) after approximation for three times. Although this method can gain a high precision frequency calculation, the calculation work of data processing is large during approximating and the calculating process is complex. Further, this solution only approximates the fundamental frequency for three times, and the precision cannot be adjusted according to actual conditions.

### SUMMARY

An object of the invention is to provide a frequency measuring method and a measuring device for an electricity system, which may address the problems that the conventional calculation process is complex and cannot gain more precise frequency results.

To this end, solutions of the invention include: A frequency measuring method for an electricity system which is not affected by aperiodic noises, including steps:

1) sampling N points in one period of the current signals to be measured, and discretizing the sampled signals;

2) from discrete sampled signals, obtaining sampling matrixes [Iₙ] and [Iₙ₋₁] of the current signals to be measured at time n and time n−1:

$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$

wherein M≦L≦N−M, L and M are set values;

3) setting a reference frequency f_{ref}, constructing a voltage signal u(t) from f_{ref} and a voltage expression, and discretizing u(t) to obtain a reference matrix:

$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} ) ;$$

4) attaining phase values θ and δₙ₋₁ corresponding to time n and time n−1 from the eigenvalues of matrixes [Iₙ]⁺[U] and [Iₙ₋₁]⁺[U], and determining a calculation frequency f_{comp} from θ and θₙ₋₁ as the frequency to be measured.

The frequency measuring method further includes steps:

5) calculating a difference between f_{comp} and f_{ref};

6) determining whether the difference is in a set error range; if yes, deeming f_{comp} as the actual value of the frequency to be measured; if not, using f_{comp}, as a new reference frequency, repeating steps 3), 4) and 5) until the difference between the calculation frequency and the reference frequency is in the set error range.

Step 4) includes a process of singular value decomposing the sampling matrixes [Iₙ] and [Iₙ₋₁].

Step 4) includes a process of QR decomposing matrixes [Iₙ]⁺[U] and [Iₙ₋₁]⁺[U]: [Iₙ]⁺[U]=[Qₙ][Λₙ][R′ₙ], [Iₙ₋₁]⁺[U]=[Qₙ₋₁][Λₙ₋₁][Rₙ₋₁′], wherein [Λₙ] and [Λₙ₋₁] are diagonal matrixes in which the former two diagonal elements are not 0 and the rest elements are 0.

The error range is less than 0.000001.

Also disclosed is a frequency measuring device for an electricity system which is not affected by aperiodic noises, including:

a first module for sampling N points in one period of the current signals to be measured, and discretizing the sampled signals;

a second module for obtaining sampling matrixes [Iₙ] and [Iₙ₋₁] of the current signals to be measured at time n and time n−1 from discrete sampled signals:

$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$

wherein M≦L≦N−M, L and M are set values;

a third module for setting a reference frequency f_{ref}, constructing a voltage signal u(t) through f_{ref} and a voltage expression, and discretizing u(t) to obtain a reference matrix:

$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} ) ;$$

a fourth module for attaining phase values θₙ and θₙ₋₁ corresponding to time n and time n−1 from the eigenvalues of matrixes [Iₙ]⁺[U] and [Iₙ₋₁]⁺[U], and determining a calculation frequency f_{comp} by θₙ and θₙ₋₁ as the frequency to be measured.

The frequency measuring device further includes: a fifth module for calculating difference between f_{comp} and f_{ref}; a sixth module for determining whether the difference is in error range, if yes, deeming f_{comp} as the actual value of the frequency to be measured; if not, using f_{comp} as a new reference frequency, repeatedly operating the third, fourth and fifth modules until the difference between the calculation frequency and the reference frequency is in the set error range.

The fourth module is also adapted to singular value decompose the sampling matrixes [Iₙ] and [Iₙ₋₁].

The fourth module is further adapted to QR decompose matrixes [Iₙ]⁺[U] and [Iₙ₋₁]⁺[U]:[Iₙ]⁺[U]=[Qₙ][Λₙ][R′ₙ], [Iₙ₋₁]⁺[U]=[Qₙ₋₁][Λₙ₋₁][R′ₙ₋₁], wherein [Λₙ] and [Λₙ₋₁] are diagonal matrixes in which the former two diagonal elements are not 0 and the rest elements are 0.

The beneficial effects of the solution are in that it uses a matrix pencil analysis method for a sampling matrix constructed from the reference signals and the signals to be measured, as well as uses the matrix singular value decomposition technique. Through QR decomposition and similarity transformation of matrixes and the eigenvalues calculation of the corresponding matrixes, phases of the matrixes to be measured are obtained. Then, the frequency of the signals to be measured is calculated through the phase difference between the former and the latter sampling moment. The present solution simplifies calculating process and reduces calculation work, in comparison to the prior art. The solution can calculate the frequencies of the sinusoidal signals quickly and precisely in the power frequency data window.

### BRIEF DESCRIPTION OF THE DRAWINGS

FIG. 1 is a flow chart of a first embodiment according to the invention.

FIG. 2 shows the frequency measuring error results during AM and FM when FM frequency is 2 Hz.

FIG. 3 (a) is a frequency measuring result graph when the value of amplitude is step changed by 10%.

FIG. 3 (b) is a frequency measuring result graph when the value of amplitude is step changed by −10%.

FIG. 3 (c) is a frequency measuring result graph when the phase is step changed by 10 degree.

FIG. 3 (d) is a frequency measuring result graph when the phase is step changed by −10 degree.

FIG. 3 (e) is a frequency measuring result graph when the frequency is step changed by 1 Hz.

FIG. 3 (f) is a frequency measuring result graph when the frequency is step changed by −1 Hz.

FIG. 4 (a) is a frequency measuring result graph at the initial phase when the frequency is rising slowly.

FIG. 4 (b) is a frequency measuring result graph at the end phase when the frequency is rising slowly.

FIG. 4(c) is a frequency measuring result graph at the initial phase when the frequency is descending slowly.

FIG. 4 (d) is a frequency measuring result graph at the end phase when the frequency is descending slowly.

FIG. 5 is a flow chart of a second method embodiment.

### DETAILED DESCRIPTION

The invention is now further described with reference to the appended drawings.

### Method Embodiment 1

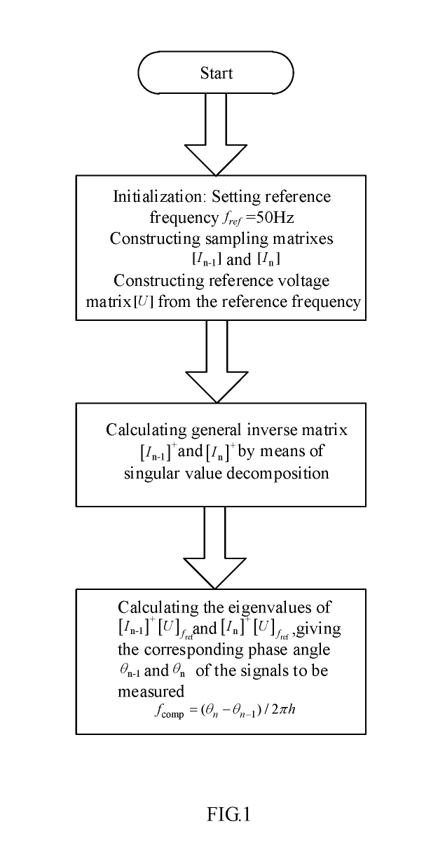

As shown in FIG. 1, the method generally includes:

1) sampling N points in one period of the electrical current signals to be measured, and discretizing the sampled signals, to attain a discrete expression of the sampled signals;

2) obtaining sampling matrixes [Iₙ] and [Iₙ₋₁] of the current signals to be measured at time n and time n−1 according to the discrete expression of the sampled signals:

$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$

wherein M≦L≦N−M;

3) setting a reference frequency f_{ref}, constructing a reference signal u(t) through f_{ref}, and discretizing u(t) to thus gain a reference matrix:

$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} ) ;$$

4) attaining phase values θₙ and θₙ₋₁ corresponding to time n and time n−1 by the eigenvalues of matrixes [Iₙ]⁺[U] and [Iₙ₋₁]⁺[U], and determining a calculation frequency f_{comp} by θₙ and θₙ₋₁.

The solution described above will be specifically explained below, taking a current signal 100[1+0.1 cos(4πt)]cos[100πt+0.1(4πt−π)] as an example:

The present embodiment relates to an electricity system whose power frequency is 50 Hz. Firstly, sampling the current signal to be measured, N points each period. Thus the sampling interval is

$$h = \frac{0.02}{N} .$$

Then, discretizing the sampled signals to attain a discrete expression of the sampled signals.

Obtaining sampling matrixes [Iₙ] and [Iₙ₋₁] of the current signal to be measured at time n and time n−1 according to the discrete expression of the sampled signals:

$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$

wherein M≦L≦N−M, L and M are set values which can be set according to the particular system itself to be measured and the measuring precise.

Utilizing a Vandermonde matrix, the sampling matrixes can be expressed as follows, respectively:

[Iₙ]=[Z₁][P]ₙ[Z₂],[Iₙ₋₁]=[Z₁][P]ₙ₋₁[Z₂],

wherein:

$$[ {Z}_{1} ] = ( \begin{matrix}1 & 1 & … & 1 \\ {z}_{1} & {z}_{2} & … & {z}_{M} \\ ⋮ & ⋮ & ⋱ & ⋮ \\ {z}_{1}^{( N - L )} & {z}_{2}^{( N - L )} & … & {z}_{M}^{( N - L )}\end{matrix} ) , \\ [ {Z}_{2} ] = ( \begin{matrix}1 & {z}_{1} & … & {z}_{1}^{( L - 1 )} \\ 1 & {z}_{2} & … & {z}_{2}^{( L - 1 )} \\ ⋮ & ⋮ & ⋱ & ⋮ \\ 1 & {z}_{M} & … & {z}_{M}^{( L - 1 )}\end{matrix} )$$

[P]ₙ=diag[p₁z₁^{n-N+1},p₂z₂^{n-N+1}, . . . ,p_{M}z_{M}^{n-N+1}],[P]ₙ₋₁=diag[p₁z₁^{n-N},p₂z₂^{n-N}, . . . ,p_{M}z_{M}^{n-N}].

The complex sampling matrixes [Iₙ] and [Iₙ₋₁] can be simplified through this step, to facilitate subsequent processing of the sampling matrixes. Of course, if the complexity is not a factor to be considered, the sampling matrixes may not be transformed as above.

The reference frequency is set as a power frequency in electricity systems, i.e. f_{ref}=50 Hz. From such a reference frequency, a reference voltage signal can be gained as u(t₁)=cos ω₁t₁, 0≦t₁≦0.02. Here, a relatively simple and regular reference voltage signal is constructed, in order to facilitate subsequent calculation of processing. As other embodiments, other u(t) expressions can also be constructed from the reference frequency.

Then, the reference signal is discretized to gain a sampling matrix corresponding to the reference signal:

$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} )$$

Similarly, by means of a Vandermonde matrix, the reference matrix can also be expressed as: [U]=[Z₁₁][P′][Z₂], wherein [P′]=diag[½,½,0 . . . ,0]. The processing methods of the reference matrix and the sampling matrix herein are identical, and thus a repeat introduction is not given.

From the sampling matrixes and reference matrix, the following expression can be gained:

$$\begin{matrix} \begin{matrix}{[ {I}_{n} ]}^{+} [ U ] = {{{[ {Z}_{2} ]}^{+} [ P ]}_{n}^{-} [ {Z}_{1} ]}^{+} [ {Z}_{1} ] [ {P}^{′} ] [ {Z}_{2} ] \\ = {{[ {Z}_{2} ]}^{+} [ P ]}_{n}^{-} [ {P}^{′} ] [ {Z}_{2} ]\end{matrix} \\ \begin{matrix}{[ P ]}_{n}^{-} [ {P}^{′} ] = {{[ {Z}_{2} ] [ {I}_{n} ]}^{+} [ U ] [ {Z}_{2} ]}^{+} \\ = diag [ \frac{1}{{A}_{1} {e}^{j [ {ω}_{1} ( n - N + 1 ) h + {ϕ}_{1} ]}} , \frac{1}{{A}_{1} {e}^{- j [ {ω}_{1} ( n - N + 1 ) h + {ϕ}_{1} ]}} , 0 , … , 0 ]\end{matrix}\end{matrix}$$

similarly,

$$\begin{matrix}{[ P ]}_{n - 1}^{-} [ {P}^{′} ] = {{[ {Z}_{2} ] [ {I}_{n - 1} ]}^{+} [ U ] [ {Z}_{2} ]}^{+} \\ = diag [ \frac{1}{{A}_{1} {e}^{j [ {ω}_{1} ( n - N ) h + {ϕ}_{1} ]}} , \frac{1}{{A}_{1} {e}^{- j [ {ω}_{1} ( n - N ) h + {ϕ}_{1} ]}} , 0 , … , 0 ]\end{matrix}$$

The eigenvalues calculation of high order matrixes can be transformed into the eigenvalues calculation of 2-order matrixes through QR decomposition and similarity transformation, which largely simplifies calculation process, but in the case that calculation complexity is not a factor to be considered, the high order matrixes can also be simplified using other matrix transforming methods and decomposition means, or the eigenvalues of the matrixes can be calculated directly.

With the calculated eigenvalues, the amplitude and phase of the signals to be measured can be determined. The process is as follows: if the phase corresponding to time n is θₙ=ω₁(n−N+1)h+φ₁, the phase corresponding to time n−1 is θₙ₋₁=ω₁(n−N)h+φ₁, because of θₙ−θₙ₋₁=ω₁h, the calculated frequency value is:

$${f}_{1} = \frac{{θ}_{n} - {θ}_{n - 1}}{2 π h}$$

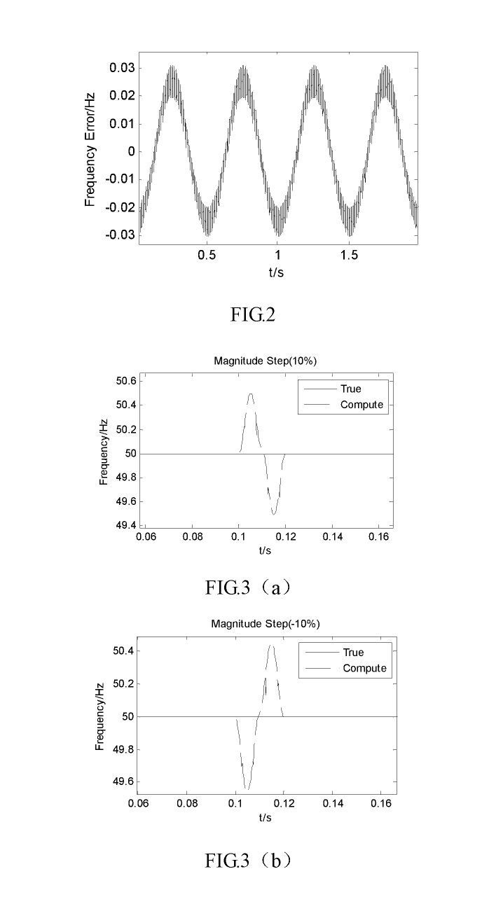

FIG. 2 shows a frequency measuring result graph obtained. As can be seen from the figure, the solution can exactly obtain the calculation frequency of the signals to be measured.

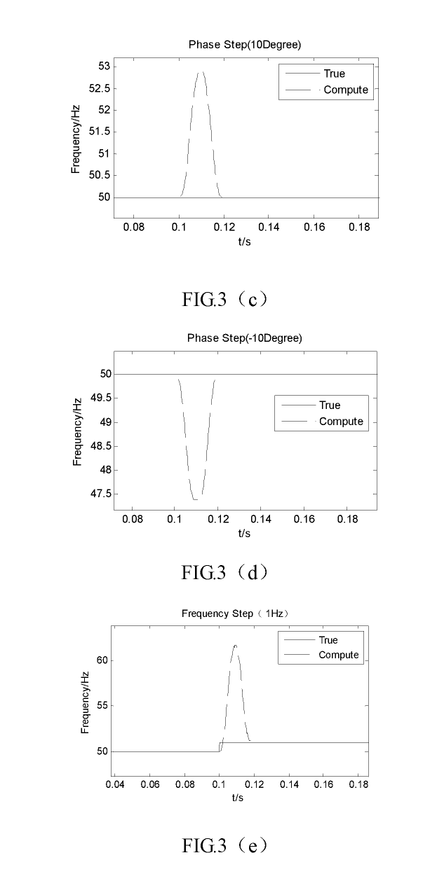

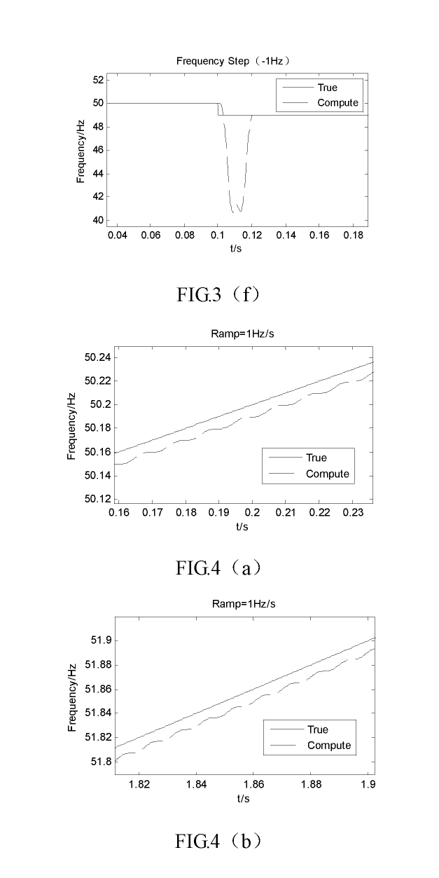

In addition, FIG. 3 shows the frequency measuring results when amplitude, phase and frequency of the signals are changed suddenly. As can be seen from the figure, the proposed method of the invention is not affected by suddenly changes in amplitude, phase and frequency, and response time of the frequency is not more than 20 ins.

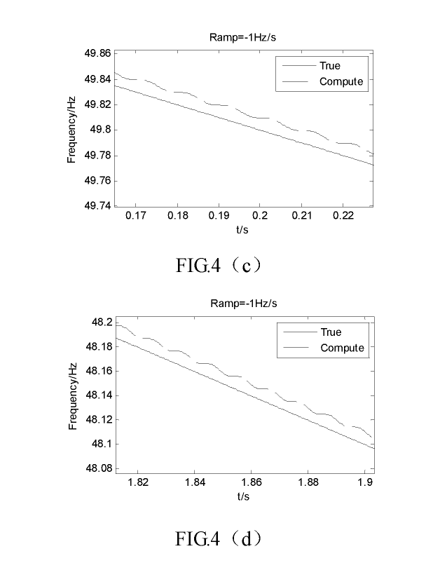

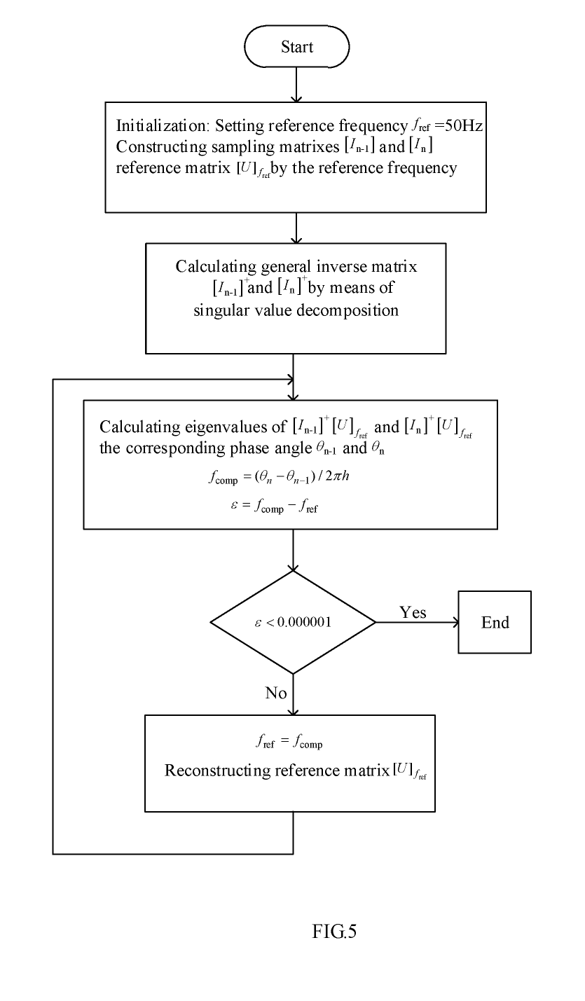

FIG. 4 shows the frequency measuring results when the frequency is rising slowly (1 Hz/s) and descending (−1 Hz/s) slowly. As can be seen from the figure, the proposed method of the invention can trace the change of the frequency quickly.

### Method Embodiment 2

As shown in FIG. 5, the implementation process of this embodiment is substantially identical with the embodiment 1, except that there is a calculation result verifying process in this embodiment. The specific process is as follows:

A difference between the calculated frequency value and the set reference frequency value is determined as ε=f_{comp}−f_{ref}. When ε is less than 0.000001, the calculated frequency value is determined as the actual frequency value of the signals to be measured; and when ε is equal to or more than 0.000001, the calculated frequency value is designated as the reference frequency value, i.e., f_{comp}=f_{ref}. Then the reference matrix [U]_{f}_{_{ref}} is reconstructed by means of the new reference frequency value. Repeating the above calculating process, and calculating the frequency of the signal to be measured through successive iterations. The calculated frequency last time is designated as the frequency of the reference signal in each iteration. Reconstructing the reference matrix until the difference between the calculated frequency value and the corresponding reference frequency value is less than 0.000001, the calculated frequency value at this moment is the actual frequency value of the signals to be measured.

As other embodiments, the difference described above may be selected depending on the actual conditions and error precise.

### Device Embodiment

The embodiment of the frequency measuring device of the invention is a soft frame which is completely corresponding to the flow in the embodiment 1, which is no longer described herein.

Specific embodiments have been given above, but the invention is not limited to the described embodiments. A basic idea of the invention lies in the basic solution described above. According to the teachings of the invention, one of ordinary skill in the art will design various models, formulas and parameters without inventive efforts. Changes, modifications, alternatives and variants made to the embodiments are still within the scope of the invention without departing from the principle and spirit of the invention.

What is claimed is:

1. A frequency measuring method for an electricity system which is not affected by aperiodic noises, including steps:
1) sampling N points in one period of the current signals to be measured, and discretizing the sampled signals;
2) obtaining sampling matrixes [Iₙ] and [Iₙ₋₁] of the current signals to be measured at time n and time n−1 from the discrete sampled signals:
$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$
wherein M≦L≦N−M, L and M are set values;
3) setting a reference frequency f_{ref}, constructing a voltage signal u(t) from f_{ref} and a voltage expression, and discretizing u(t) to obtain a reference matrix:
$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} ) ;$$
and
4) attaining phase values θₙ and θₙ₋₁ corresponding to time n and time n−1 from the eigenvalue of matrixes [Iₙ]⁺[U] and [Iₙ₋₁]⁺[U], and determining a calculation frequency f_{comp} from θₙ and θₙ₋₁ as the frequency to be measured.

2. The frequency measuring method for the electricity system according to claim 1, further includes steps:
5) calculating a difference between f_{comp} and f_{ref}; and
6) determining whether the difference is in a set error range; if yes, determining f_{comp} as the actual value of the frequency to be measured; if not, designating f_{comp} as a new reference frequency, then repeating steps 3), 4) and 5) until the difference between the calculation frequency and the reference frequency is in the set error range.

3. The frequency measuring method for an electricity system according to claim 1, wherein step 4) includes a process of singular value decomposing the sampling matrixes [Iₙ] and [Iₙ₋₁].

4. The frequency measuring method for the electricity system according to claim 3, wherein step 4) includes a process of QR decomposing matrixes [Iₙ]⁺[U] and [Iₙ₋₁]⁺[U]:[Iₙ]⁺[U]=[Qₙ][Λₙ][R′ₙ], [Iₙ₋₁]⁺[U]=[Qₙ₋₁][Λₙ₋₁][R′ₙ₋₁], wherein [Λₙ] and [Λₙ₋₁] are diagonal matrixes in which the former two diagonal elements are not 0 and the rest elements are 0.

5. The frequency measuring method for the electricity system according to claim 2, wherein said error range is less than 0.000001.

6. A frequency measuring device for an electricity system which is not affected by aperiodic noises, including:
a first module configured to sample N points in one period of the current signals to be measured, and discretize the sampled signals;
a second module configured to obtain sampling matrixes [Iₙ] and [Iₙ₋₁] of the current signals to be measured at time n and time n−1 from discrete sampled signals:
$$[ {I}_{n} ] = ( \begin{matrix}i ( n - N + 1 ) & i ( n - N + 2 ) & … & i ( n - N + L ) \\ i ( n - N + 2 ) & i ( n - N + 3 ) & … & i ( n - N + L + 1 ) \\ ⋮ & ⋮ & ⋱ & ⋮ \\ i ( n - L + 1 ) & i ( n - L + 2 ) & … & i ( n )\end{matrix} ) , \\ [ {I}_{n - 1} ] = ( \begin{matrix}i ( n - N ) & i ( n - N + 1 ) & … & i ( n - N + L - 1 ) \\ i ( n - N + 1 ) & i ( n - N + 2 ) & … & i ( n - N + L ) \\ ⋮ & ⋮ & ⋱ & ⋮ \\ i ( n - L ) & i ( n - L + 1 ) & … & i ( n - 1 )\end{matrix} ) ,$$
in which M≦L≦N−M, L and M are set values;
a third module configured to set a reference frequency f_{ref}, construct a voltage signal u(t) from f_{ref} and a voltage expression, and discretize u(t) to thus gain a reference matrix:
$$[ U ] = ( \begin{matrix}u ( 0 ) & u ( 1 ) & … & u ( L - 1 ) \\ u ( 1 ) & u ( 2 ) & … & u ( L ) \\ ⋮ & ⋮ & ⋱ & ⋮ \\ u ( N - L ) & u ( N - L + 1 ) & … & u ( N - 1 )\end{matrix} ) ;$$
and
a fourth module configured to attain phase values θₙ and θₙ₋₁ corresponding to time n and time n−1 from the eigenvalues of matrixes [Iₙ]⁺[U] and [Iₙ₋₁]⁺[U], and determine a calculation frequency f_{comp} from θₙ and θₙ₋₁ as the frequency to be measured.

7. The frequency measuring device for the electricity system according to claim 6, further includes:
a fifth module configured to calculate a difference between f_{comp} and f_{ref}; and
a sixth module configured to determine whether the difference is in a set error range, if yes, determining f_{comp} as the actual value of the frequency to be measured; if not, designating f_{comp} as a new reference frequency, then repeatedly operating the third, fourth and fifth modules until the difference between the calculation frequency and the reference frequency is in the set error range.

8. The frequency measuring device for the electricity system according to claim 6, wherein the fourth module is further configured to singular value decompose the sampling matrixes [Iₙ] and [Iₙ₋₁].

9. The frequency measuring device for an electricity system according to claim 8, wherein the fourth module is further configured to, QR decompose matrixes [Iₙ]⁺[U] and [Iₙ₋₁]⁺[U]:[Iₙ]⁺[U]=[Qₙ][Λₙ][R′ₙ], [Iₙ₋₁]⁺[U]=[Qₙ₋₁][Λₙ₋₁][R′ₙ₋₁], wherein [Λₙ] and [Λₙ₋₁] are diagonal matrixes in which the former two diagonal elements are not 0 and the rest elements are 0.
